(19) United States
(12) Patent Application Publication
(10) Pub. No.: US 2024/0243216 A1
(43) Pub. Date: Jul. 18, 2024

(54) LIGHT SENSING DEVICE AND METHOD OF MANUFACTURING THE SAME, IMAGE SENSOR INCLUDING LIGHT SENSING DEVICE, AND ELECTRONIC APPARATUS INCLUDING IMAGE SENSOR

(71) Applicant: SAMSUNG ELECTRONICS CO., LTD., Suwon-si (KR)

(72) Inventors: Kyungsang CHO, Suwon-si (KR); Chanwook BAIK, Suwon-si (KR); Yooseong YANG, Suwon-si (KR)

(73) Assignee: SAMSUNG ELECTRONICS CO., LTD., Suwon-si (KR)

(21) Appl. No.: 18/413,897

(22) Filed: Jan. 16, 2024

(30) Foreign Application Priority Data
Jan. 16, 2023 (KR) 10-2023-0006311

(51) Int. Cl. H01L 31/113; H01L 31/028; H01L 31/18

(52) U.S. Cl. CPC H01L 31/1136; H01L 31/028; H01L 31/1808

(57) ABSTRACT

A light sensing device includes a channel layer, a first electrode provided on a first surface of the channel layer, a second electrode provided on the first surface of the channel layer and spaced apart from the first electrode, and a light absorption layer provided on the channel layer between the first electrode and the second electrode and configured to absorb infrared rays, where the light absorption layer includes a doped semiconductor layer.

### CROSS-REFERENCE TO RELATED APPLICATION

This application is based on and claims priority under 35 U.S.C. § 119 to Korean Patent Application No. 10-2023-0006311, filed on Jan. 16, 2023, in the Korean Intellectual Property Office, the disclosure of which is incorporated by reference herein in its entirety.

### BACKGROUND

### 1. Field

The disclosure relates to an optical device, and more particularly, to light sensing devices, methods of manufacturing the light sensing devices, image sensors including the light sensing devices, and electronic apparatuses including the image sensors.

### 2. Description of the Related Art

A unit element of a generally used image sensor may be a silicon photodiode.

When light is incident on a depletion region of a silicon photodiode, photocarriers excited by the light are generated, and an amount of photocarriers generated may be read through a circuit. Accordingly, the intensity of incident light may be measured.

Image sensors may be classified into a visible light band image sensor and a broadband image sensor that detects light (e.g., infrared rays) of a wider band than the visible light band.

Materials used in image sensors of each band may be different from each other, and various image sensors for each band are being developed in consideration of various factors, such as a manufacturing process and economics.

### SUMMARY

One or more example embodiments provide broadband light sensing devices constructed with a simple manufacturing process.

One or more example embodiments also provide broadband light sensing devices with reduced manufacturing cost.

One or more example embodiments also provide methods of manufacturing the light sensing devices.

One or more example embodiments also provide image sensors including the light sensing devices.

One or more example embodiments also provide electronic apparatuses including the light sensing devices and/or the image sensors.

Additional aspects will be set forth in part in the description which follows and, in part, will be apparent from the description, or may be learned by practice of the presented embodiments of the disclosure.

According to an aspect of the disclosure, a light sensing device may include a channel layer, a first electrode provided on a first surface of the channel layer, a second electrode provided on the first surface of the channel layer and spaced apart from the first electrode, and a light absorption layer provided on the channel layer between the first electrode and the second electrode and configured to absorb infrared rays, where the light absorption layer may include a doped semiconductor layer.

The channel layer may include an n-type semiconductor layer.

The light absorption layer may directly contact the first surface of the channel layer.

The channel layer may include a first doped region corresponding to the first electrode and a second doped region corresponding to the second electrode.

The light absorption layer may include a doped Ge layer or a doped Si layer.

The doped semiconductor layer may be amorphous or polycrystalline.

According to an aspect of the disclosure, a light sensing device may include an insulating layer, a channel layer provided on the insulating layer, a first electrode provided on a first surface of the channel layer, a second electrode provided on the first surface of the channel layer and spaced apart from the first electrode, a light absorption layer provided on the channel layer between the first electrode and the second electrode and configured to absorb infrared rays, and a gate insulating layer provided between the channel layer and the light absorption layer, where the channel layer may include an n-type semiconductor layer, and where the light absorption layer may include an undoped semiconductor layer.

The light absorption layer may be provided between the insulating layer and the channel layer and where the light absorption layer and the gate insulating layer may be at least partially covered by the insulating layer.

The light sensing device may include a first semiconductor layer, where the insulating layer may be between the first semiconductor layer and the channel layer.

The first semiconductor layer may include a p-type semiconductor layer.

The first semiconductor layer may include a semiconductor layer of a type that is the same as a type of the channel layer.

The channel layer may include a first doped region corresponding to the first electrode and a second doped region corresponding to the second electrode.

The light absorption layer may include a Ge layer.

According to an aspect of the disclosure, a method of manufacturing a light sensing device may include forming a first electrode and a second electrode on a first surface of a substrate, the first electrode and the second electrode being spaced apart and forming a light absorption layer on the substrate between the first electrode and the second electrode, the light absorption layer being configured to absorb infrared rays, where the light absorption layer may include a doped Ge layer or a doped Si layer.

The substrate may include a gate electrode.

The substrate may include a PN junction semiconductor layer, the PN junction semiconductor layer may include a P-type semiconductor layer, and the gate electrode may include the P-type semiconductor layer of the PN junction semiconductor layer.

The method may include forming an insulating layer on the substrate, the insulating layer covering the first electrode and the second electrode, and removing a portion of the insulating layer that is between the first electrode and the second electrode.

The light absorption layer may be formed to fill an area between the first electrode and the second electrode corresponding to the portion of the insulating layer that is removed, and where the light absorption layer may extend onto the insulating layer.

The method may include forming an insulating layer on the substrate, the insulating layer covering the first electrode and the second electrode, forming a mask pattern including a first portion covering the first electrode and a second portion covering the second electrode, and removing a portion of the insulating layer between the first portion of the mask pattern and the second portion of the mask pattern.

The light absorption layer may be formed in an area corresponding to the removed portion of the insulating layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1, 2, 3, 4, 5, 6 and 7 are cross-sectional views illustrating first to sixth light sensing devices and modified examples, according to an example embodiment;

FIG. 8 is a graph showing results of an experiment conducted to confirm a light response of a light sensing device according to an example embodiment;

FIG. 9 is a diagram illustrating a pixel array of an infrared image sensor according to an example embodiment;

FIG. 10 is a cross-sectional view illustrating an image sensor including the pixel array of FIG. 9 according to an example embodiment;

FIGS. 11, 12, 13, 14, 15 and 16 are cross-sectional views illustrating a method of manufacturing a light sensing device, according to an example embodiment;

FIGS. 17, 18, 19 and 20 are cross-sectional views illustrating a method of manufacturing a light sensing device, according to an example embodiment, and

FIGS. 21, 22, 23 and 24 are cross-sectional views illustrating a method of manufacturing a light sensing device, according to an example embodiment.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a light sensing device, a method of manufacturing the light sensing device, an image sensor including the light sensing device, and an electronic apparatus including the image sensor according to example embodiments will be described in detail with reference to the accompanying drawings. The drawings are not to scale, and thicknesses of layers and regions may be exaggerated for clarification of the specification.

In addition, example embodiments may be variously modified and may be embodied in many different forms. When an element or layer is referred to as being “on” or “above” another element or layer, the element or layer may be directly on another element or layer or intervening elements or layers. In the description below, like reference numerals in each drawing denote like members.

The singular forms are intended to include the plural forms as well, unless the context clearly indicates otherwise. When a part “comprises” or “includes” an element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the terms “units” or “. . . modules” denote units or modules that process at least one function or operation, and may be realized by hardware, software, or a combination of hardware and software.

Connections or connection members of lines between components shown in the drawings illustrate functional connections and/or physical or circuit connections, and the connections or connection members may be represented by replaceable or additional various functional connections, physical connections, or circuit connections in an actual apparatus.

The use of any and all examples, or exemplary language provided herein, is intended merely to better illuminate the inventive concept and does not pose a limitation on the scope of the disclosure unless otherwise claimed.

First, light sensing devices according to example embodiments will be described.

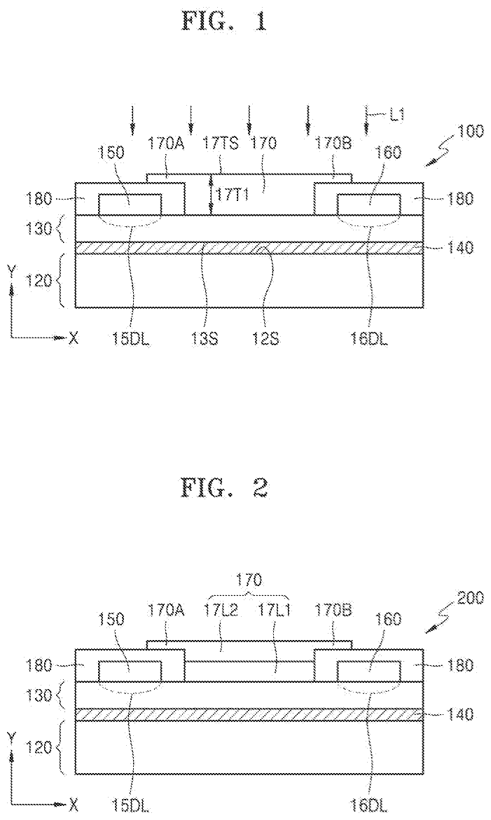

FIGS. 1, 2, 3, 4, 5, 6 and 7 are cross-sectional views illustrating first to sixth light sensing devices and modified examples, according to an example embodiment.

FIG. 1 shows a first light sensing device 100 according to an example embodiment.

Referring to FIG. 1, the first light sensing device 100 includes a first semiconductor layer 120, a second semiconductor layer 130, an interlayer insulating layer 140 between the first semiconductor layer 120 and the second semiconductor layer 130, a first electrode 150, a second electrode 160, and a light absorption layer 170. The first electrode 150, the second electrode 160, and the light absorption layer 170 are provided on the second semiconductor layer 130. The first semiconductor layer 120, the interlayer insulating layer 140, and the second semiconductor layer 130 may be sequentially provided. The first and second semiconductor layers 120 and 130 and the interlayer insulating layer 140 may collectively be referred to as a substrate.

The interlayer insulating layer 140 is on one surface 12S (e.g., an upper surface) of the first semiconductor layer 120. The interlayer insulating layer 140 may directly contact the surface 12S. The interlayer insulating layer 140 may be formed to cover the entire surface 12S. The interlayer insulating layer 140 is also on one surface 13S (e.g., a lower surface) of the second semiconductor layer 130. The interlayer insulating layer 140 may directly contact the surface 13S. The interlayer insulating layer 140 may be formed to cover the entire surface 13S.

In one example, the first semiconductor layer 120 may be formed only on a partial region of the interlayer insulating layer 140. In this case, the first semiconductor layer 120 may be located between the first and second electrodes 150 and 160 in a horizontal direction (e.g., an X-axis direction), and may be provided to face the light absorption layer 170.

One of the first and second semiconductor layers 120 and 130 may be a P-type semiconductor layer doped with a P-type impurity, and the other of the first and second semiconductor layers 120 and 130 may be an N-type semiconductor layer doped with an N-type impurity. For example, the first semiconductor layer 120 may be a P+ semiconductor layer, and the second semiconductor layer 130 may be an N− semiconductor layer. In one example, the P+ semiconductor layer may include a P+ silicon (Si) layer. In one example, the N− semiconductor layer may include an N—Si layer. In one example, the interlayer insulating layer 140 may be a depletion layer, and the depletion layer may be formed as a result of junction of the first semiconductor layer 120 and the second semiconductor layer 130. In other words, the interlayer insulating layer 140 may correspond to a junction region between the first semiconductor layer 120 and the second semiconductor layer 130. In this case, the first semiconductor layer 120, the interlayer insulating layer 140, and the second semiconductor layer 130 may collectively be referred to as a PN junction semiconductor layer. In this case, the first semiconductor layer 120 may serve as a gate electrode, the interlayer insulating layer 140 may serve as a gate insulating layer, and the second semiconductor layer 130 may serve as a channel, and the second semiconductor layer 130 may be referred to as a channel layer. One of the first and second electrodes 150 and 160 may be a source electrode and the other may be a drain electrode. The first and second semiconductor layers 120 and 130, the interlayer insulating layer 140, and the first and second electrodes 150 and 160 may have a layer structure or a layer configuration forming a junction field effect transistor (JFET).

Accordingly, in an operation of the first light sensing device 100, a carrier (e.g., current) flowing between the first electrode 150 and the second electrode 160 through the second semiconductor layer 130 (e.g., a channel layer) may be controlled by a voltage applied to the first semiconductor layer 120.

In one example, the first and second electrodes 150 and 160 may be electrodes formed with the same conductive material, but may also be electrodes formed with different conductive materials. In one example, each of the electrodes 150 and 160 may include one type of metal or may include two different types of metals.

In one example, the second semiconductor layer 130 may include first and second doped regions (or doped layers) 15DL and 16DL in regions corresponding to the first and second electrodes 150 and 160. The first doped region 15DL may serve to reduce contact resistance between the second semiconductor layer 130 and the first electrode 150, and the second doped region 16DL may serve to reduce contact resistance between the second semiconductor layer 130 and the second electrode 160.

The first doped region 15DL is located below the first electrode 150 and may directly contact the first electrode 150. The first doped region 15DL may be below the first electrode 150, and may be diffused laterally under the condition that the first doped region 15DL does not contact the light absorption layer 170. The first doped region 15DL may extend through the entire thickness of the second semiconductor layer 130 immediately below the first electrode 150.

The second doped region 16DL is located below the second electrode 160 and may directly contact the second electrode 160. The second doped region 16DL may be below the second electrode 160, and may be diffused laterally under the condition that the second doped region 16DL does not contact the light absorption layer 170. Also, the second doped region 16DL may extend through the entire thickness of the second semiconductor layer 130 immediately below the second electrode 160.

In one example, the first and second doped regions 15DL and 16DL may be regions doped with the same type of doping material (dopant) used for doping the second semiconductor layer 130. Doping concentrations of the first and second doped regions 15DL and 16DL may be different from those of other regions of the second semiconductor layer 130. For example, the first and second doped regions 15DL and 16DL may be regions doped with an n-type impurity and may have a higher doping concentration than other regions of the second semiconductor layer 130.

In one example, when a contact resistance between the first and second electrodes 150 and 160 and the second semiconductor layer 130 is low enough not to interfere with the operation of the first light sensing device 100, the first and second doped regions 15DL and 16DL may be omitted.

The light absorption layer 170 may be provided on the second semiconductor layer 130 between the first electrode 150 and the second electrode 160. The light absorption layer 170 and the first and second electrodes 150 and 160 are separated from each other and do not contact each other. An insulating layer 180 may be present between the light absorption layer 170 and the first and second electrodes 150 and 160. The insulating layer 180 may be configured to contact both the light absorption layer 170 and the first and second electrodes 150 and 160. The insulating layer 180 may be provided such that the light absorption layer 170 and the first and second electrodes 150 and 160 do not contact each other. The insulating layer 180 may cover the first and second electrodes 150 and 160, and may cover or at least partially cover an area of the second semiconductor layer 130 between the electrodes 150/160 and the light absorption layer 170. The insulating layer 180 may be between the light absorption layer 170 and the first electrode 150, and may be configured to completely cover portions of the first electrode 150 facing the light absorption layer 170. The insulating layer 180 may be between the light absorption layer 170 and the second electrode 160, and may be configured to completely cover portions of the second electrode 160 facing the light absorption layer 170. In one example, the insulating layer 180 may include oxide or nitride. In one example, the oxide may be silicon oxide (e.g., SiO₂) or include silicon oxide, but is not limited thereto. In one example, the nitride may be or include silicon nitride, but is not limited thereto.

In one example, the light absorption layer 170 may include portions 170A and 170B extending over portions of the insulating layer 180 on the first and second electrodes 150 and 160. Accordingly, the portion 170A of the light absorption layer 170 may overlap a portion of the first electrode 150 and a portion of the second electrode 160, and the insulating layer 180 may be positioned therebetween. In one example, a length of the portion 170A of the light absorption layer 170 extending over the first electrode 150 may be equal to or substantially equal to a length of the portion 170B extending over the second electrode 160. Alternatively, in one example, a length of the portion 170A of the light absorption layer 170 extending over the first electrode 150 may be different from a length of the portion 170B extending over the second electrode 160. In one example, a thickness of the portion 170A of the light absorption layer 170 extending onto the first electrode 150 may be equal to or substantially equal to a thickness of the portion 170B extending onto the second electrode 160. Alternatively, in one example, a thickness of the portion 170A of the light absorption layer 170 extending onto the first electrode 150 may be different from a thickness of the portion 170B extending onto the second electrode 160.

In one example, the extended portions 170A and 170B of the light absorption layer 170 may be omitted.

In one example, a height (or thickness) of the light absorption layer 170 in a vertical direction (e.g., the Y-axis direction) may be greater than heights of the first and second electrodes 150 and 160. In one example, a height (or thickness) of the light absorption layer 170 in a vertical direction (e.g., the Y-axis direction) may be less than heights of the first and second electrodes 150 and 160. In one example, a height (or thickness) of the light absorption layer 170 in a vertical direction (e.g., the Y-axis direction) may be equal to heights of the first and second electrodes 150 and 160. In one example, the thickness of the light absorption layer 170 may be uniform over the entire region. In one example, the thickness of some regions of the light absorption layer 170 may be different from that of other regions of the light absorption layer 170. In one example, a width of the light absorption layer 170 in the horizontal direction may be greater than that of any one of the first and second electrodes 150 and 160, but the width is not limited thereto.

In one example, the light absorption layer 170 may or may not directly contact the second semiconductor layer 130. An entire surface (e.g., a lower surface) of the light absorption layer 170 facing the second semiconductor layer 130 may contact the second semiconductor layer 130 serving as a channel, but it may not contact. In one example, another member (e.g., an insulating layer) may be further provided between a surface of the light absorption layer 170 facing the second semiconductor layer 130 and the second semiconductor layer 130.

In one example, an entire upper surface 17TS of the light absorption layer 170 may be configured to be a flat surface, or to be a non-flat surface (i.e., a stepped surface). For example, a step difference (of two or more steps) may be formed between portions of the upper surface 17TS of the light absorption layer 170 (i.e., a first portion of the upper surface 17TS may be at a height that is different from a remaining portion of the upper surface 17TS).

In one example, a thickness 17T1 of the light absorption layer 170 may be determined in consideration of optical properties (e.g., light absorptance, photoelectric conversion efficiency, etc.) of a material used, a wavelength of incident light, a size of a light sensing element, etc. In one example, the thickness 17T1 of the light absorption layer 170 may be about 5 nm to about 10,000 nm, but the thickness 17T1 is not limited thereto.

In one example, a material of the light absorption layer 170 may be or include a material that absorbs light of a broadband wavelength and has a relatively high photoelectric conversion efficiency for such light. The broadband wavelength may not include wavelengths in the visible light band, but may include wavelengths at an edge of the visible light band (e.g., wavelengths near the infrared band). In one example, the broadband wavelength may include a wavelength of the infrared band, (e.g., short wave infrared (SWIR), medium wave infrared (MWIR), long wave infrared (LWIR), etc.). In one example, the wavelength of the SWIR may be about 1100 nm to about 1650 nm, but is not limited thereto.

In one example, the light absorption layer 170 may include an undoped or substantially undoped semiconductor layer, or a doped semiconductor layer. In one example, the undoped semiconductor layer may be a germanium (Ge) layer or include germanium.

In one example, the doped semiconductor layer may be a doped Ge layer or a doped Si layer, and may include such a layer, but the doped semiconductor layer is not limited thereto.

In one example, the undoped or doped Ge layer may be in an amorphous state or a polycrystalline state, or may be in a single crystal state formed by epitaxy. Among the materials of the light absorption layer 170, the crystalline state of another semiconductor layer may be amorphous, polycrystalline, or single crystalline, similar to the Ge layer.

In one example, when the light absorption layer 170 is a doped Si layer, the dopant may include one or at least one of phosphorus (P), arsenic (As), gallium (Ga), and indium (In), but the dopant is not limited thereto. The doping amount or doping concentration of the doped Si layer may be in a range from about 10¹⁵/cm² to about 10²⁰/cm².

In one example, when the light absorption layer 170 is a doped Ge layer, the dopant may include one or at least one of Ga, beryllium (Be), zinc (Zn), and arsenic (As), but is not limited thereto. The doping amount or doping concentration of the doped Ge layer may be in a range from about 10¹⁵/cm² to about 10²⁰/cm².

In the first light sensing device 100, when light L1 is incident to the light absorption layer 170, a photoelectric current is generated in the light absorption layer 170 by photoelectric conversion, and when the light L1 is not incident to the light absorption layer 170, no photoelectric current is generated. Accordingly, the light absorption layer 170 may perform as a photogate.

Because the light absorption layer 170 directly contacts the second semiconductor layer 130 (e.g., a channel layer), a light current generated in the light absorption layer 170 flows into the second semiconductor layer 130, and flows through the second semiconductor layer 130.

In an operation of the first light sensing device 100, an operating voltage is applied to the first semiconductor layer 120 (e.g., a gate electrode) and the first and second electrodes 150 and 160. When light L1 is not incident, a photoelectric current is not generated, and only a dark current generated by the operating voltage flows in the second semiconductor layer 130 between the first and second electrodes 150 and 160. Because the dark current exists when an operating voltage is applied regardless of whether light L1 is incident or not, it may be regarded as a basic current.

When light L1 is incident on the light absorption layer 170 and, as a result, a photoelectric current is generated, an amount of current, in which the photoelectric current is added to the dark current, flows through the second semiconductor layer 130.

When the light L1 is incident on the first light sensing device 100 as described above, the current flowing through the second semiconductor layer 130 is increased than the basic current due to the photoelectric current, and thus, incident of the light L1 may be detected by measuring a current flowing through the second semiconductor layer 130.

Because the amount of light current varies according to the intensity of the incident light L1, the amount of current flowing through the second semiconductor layer 130 also varies according to the intensity of the incident light L1. Accordingly, the intensity of the light L1 incident on the first light sensing device 100 may be measured by measuring the current flowing through the second semiconductor layer 130.

Because the current flowing through the second semiconductor layer 130 is the current flowing through the first light sensing device 100, the change in the current flowing through the second semiconductor layer 130 may be measured by comparing a current value measured by the first light sensing device 100 with a current value measured by a reference device. A current value measured by the reference device may correspond to a value of a dark current.

FIG. 2 shows a third light sensing device 200 according to an example embodiment. Description of elements similar to those as described with respect to the first light sensing device 100 of FIG. 1 may be omitted.

The light absorption layer 170 may be a single layer, but as in the case of a second light sensing device 200 illustrated in FIG. 2, the light absorption layer 170 may include first and second light absorption layers 17L1 and 17L2 sequentially stacked. In one example, the first light absorption layer 17L1 may be one of the materials of the light absorption layer 170 described with reference to FIG. 1, and the second light absorption layer 17L2 may also be one of the materials of the light absorption layer 170 described with reference to FIG. 1, but the materials of the first and second light absorption layers 17L1 and 17L2 may be different from each other. For example, one of the first and second light absorption layers 17L1 and 17L2 may be a Ge layer (doped or undoped) or include a Ge layer, and the other layer of the first and second light absorption layers 17L1 and 17L2 may be a doped Si layer or include such a Si layer.

In one example, the materials of the first and second light absorption layers 17L1 and 17L2 may be the same, but only the doping concentrations may be different. For example, both the first and second light absorption layers 17L1 and 17L2 may include a Ge layer, but one of the first and second light absorption layers 17L1 and 17L2 may be a Ge layer having a first doping concentration, and the other of the first and second light absorption layers 17L1 and 17L2 may be a Ge layer having a second doping concentration different from the first doping concentration.

In addition, as an example, both the first and second light absorption layers 17L1 and 17L2 may be Ge layers, but one of the first and second light absorption layers 17L1 and 17L2 may be an undoped Ge layer and the other of the first and second light absorption layers 17L1 and 17L2 may be a doped Ge layer.

Also, for example, one of the first and second light absorption layers 17L1 and 17L2 may be a Si layer having a first doping concentration, and the other of the first and second light absorption layers 17L1 and 17L2 may be a Si layer having a second doping concentration different from the first doping concentration.

In the various above examples, the main light absorption bands of the first and second light absorption layers 17L1 and 17L2 may all be in the infrared band, but the light absorption bands of the first and second light absorption layers 17L1 and 17L2 in the infrared band may be different from each other, and materials of the first and second light absorption layers 17L1 and 17L2 may be selected in consideration of this point.

In one example, the main light absorption bands of the first and second light absorption layers 17L1 and 17L2 may be different from each other. For example, one of the first and second light absorption layers 17L1 and 17L2 may include a material absorbing infrared band light, and the other of the first and second light absorption layers 17L1 and 17L2 may include a material absorbing visible light band light.

In one example, the light absorption layer 170 has a multilayer structure including a plurality of layers, and may include two or more light absorption layers. In embodiments where the light absorption layer 170 includes more than two light absorption layers, the layer configuration or layer structure of the light absorption layer 170 may be designed based on various examples of the first and second light absorption layers 17L1 and 17L2 described above.

The layer configuration and layer structure of the light absorption layer 170 described with reference to FIG. 2 may also be applied to other light sensing devices described below.

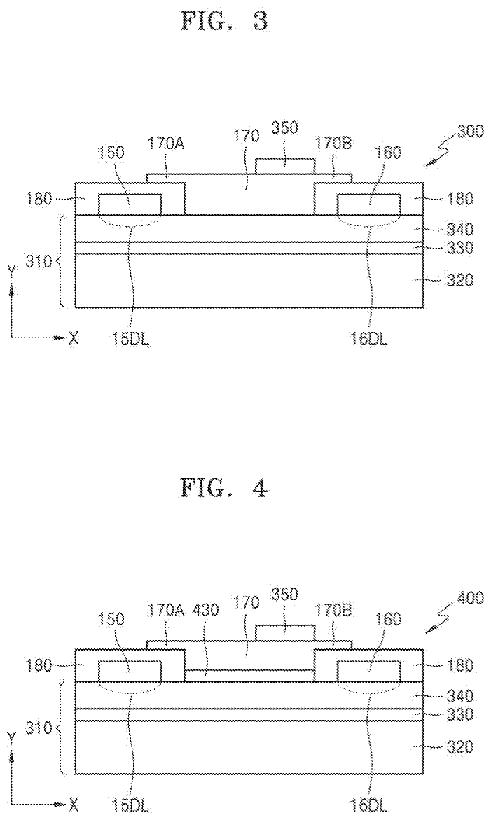

FIG. 3 shows a third light sensing device 300 according to an example embodiment.

Description of elements similar to those as described with respect to the first light sensing device 100 of FIG. 1 may be omitted.

Referring to FIG. 3, the third light sensing device 300 includes a substrate 310, first and second electrodes 150 and 160 formed on the substrate 310, and a light absorption layer 170. A third electrode 350 is provided on the light absorption layer 170.

The substrate 310 includes a lower layer 320, an intermediate layer 330, and an upper layer 340 sequentially stacked. The lower layer 320 may be of a material having conductivity or include such a material. In one example, the lower layer 320 may be or include a doped semiconductor layer, but the lower layer 320 is not limited thereto. For example, the lower layer 320 may include a doped Si layer, but the lower layer 320 is not limited thereto. The lower layer 320 may be used as a gate electrode.

In one example, the lower layer 320 may be provided to cover an entire lower surface of the intermediate layer 330, but may also be provided only on a part of the lower surface of the intermediate layer 330, or may be provided to correspond to the light absorption layer 170 between the first and second electrodes 150 and 160.

The role of lower layer 320 may be the same as or substantially the same as the role of the first semiconductor layer 120 of the first light sensing device 100. That is, the lower layer 320 may be an electrode that electrically controls the channel.

The intermediate layer 330 may be or may include an insulating layer. For example, the intermediate layer 330 may be a material layer formed as a gate insulating layer corresponding to the lower layer 320 serving as a gate electrode. In one example, the intermediate layer 330 may include oxide, nitride, or oxynitride. In one example, the intermediate layer 330 may include silicon oxide (e.g., SiO₂), but is not limited thereto. In one example, the intermediate layer 330 may include silicon nitride (e.g., Si₃N₄), but the intermediate layer 330 is not limited thereto. The intermediate layer 330 may correspond to the interlayer insulating layer 140 of the first light sensing device 100.

The upper layer 340 may be used as a channel. Therefore, the upper layer 340 may correspond to the second semiconductor layer 130 of the first light sensing device 100. In one example, the upper layer 340 may directly contact an upper surface of the intermediate layer 330 and cover the entire upper surface of the intermediate layer 330. In one example, the upper layer 340 may be or include a doped semiconductor layer, but the upper layer 340 is not limited thereto. For example, the upper layer 340 may include a doped Si layer. Because the upper layer 340 serves as a channel, the upper layer 340 may be electrically controlled by the lower layer 320 during operation of the third light sensing device 300.

The arrangement relationship between the first and second electrodes 150 and 160 and the light absorption layer 170 with respect to the substrate 310 may be the same as the arrangement relationship between the first and second electrodes 150 and 160 and the light absorption layer 170 with respect to the substrate (i.e., the first semiconductor layer 120, the second semiconductor layer 130, and the interlayer insulating layer 140) of the first light sensing device 100, although the arrangement may vary as will be understood by one of ordinary skill in the art from the disclosure herein.

Considering the roles/functions of the lower layer 320, the intermediate layer 330, and the upper layer 340, a layer structure including the lower layer 320, the intermediate layer 330, the upper layer 340, the first electrode 150, and the second electrode 160 may correspond to a field effect transistor.

The third electrode 350 is provided on an upper surface of the light absorption layer 170 and may contact the upper surface of the light absorption layer 170. The third electrode 350 may include a material layer transparent to incident light. In one example, the third electrode 350 may be provided to cover the entire upper surface of the light absorption layer 170 between the extended portions 170A and 170B, but may be provided only on a partial region of the upper surface of the light absorption layer 170 or may be provided on any one of the extended portions 170A and 170B.

When the third light sensing device 300 is operated, an operating voltage (e.g., a gate voltage) for controlling carrier movement in the upper layer 340 which is used as a channel may be applied to at least one of the lower layer 320 and the third electrode 350. The operating voltage may be applied to both the lower layer 320 and the third electrode 350. One of the lower layer 320 and the third electrode 350 may be a first gate electrode, and the other may be a second gate electrode.

As a result, the third light sensing device 300 may be a double gate light sensing device including the third electrode (top gate) 350 and the lower layer (bottom gate) 320. In the third light sensing device 300, because the third electrode 350 is provided on the light absorption layer 170, the light absorption layer 170 may serve as an electrical gate as well as a light gate.

FIG. 4 shows a fourth light sensing device 400 according to an example embodiment. Description of elements similar to those as described above may be omitted.

Referring to FIG. 4, in the fourth light sensing device 400, the light absorption layer 170 and the upper layer 340 do not directly contact each other. To this end, an insulating layer 430 may be provided between the light absorption layer 170 and the upper layer 340. The insulating layer 430 may be formed on the second semiconductor layer 340 between the first electrode 150 and the second electrode 160 and directly contact the second semiconductor layer 340. The insulating layer 430 is formed to cover the entire upper surface of the second semiconductor layer 340 between the first electrode 150 and the second electrode 160. The insulating layer 430 may be used as a gate insulating layer corresponding to the third electrode 350. In one example, the third electrode 350 and the light absorption layer 170 may be bundled together and regarded as a gate electrode, and in this case, the insulating layer 430 may be a gate insulating layer with respect to a gate electrode composed of the third electrode 350 and the light absorption layer 170.

In one example, the insulating layer 430 may include the same material as the intermediate layer 330 or the same type of material as the intermediate layer 330. In one example, the insulating layer 430 and the intermediate layer 330 may include different materials selected from among material that may be used as a gate insulating layer.

Because the insulating layer 430 is provided between the light absorption layer 170 and the second semiconductor layer 340 in the fourth light sensing device 400, the role of the light absorption layer 170 as a light gate or an electrical gate may be limited.

Specifically, even if a photoelectric current is generated in the light absorption layer 170 according to light incident, it is difficult for the photoelectric current to be injected into the second semiconductor layer 130 (i.e., a channel layer) due to the insulating layer 430. However, the photoelectric current generated in the light absorption layer 170 (i.e., an electric field) may reach the second semiconductor layer 340. Therefore, in the case of the fourth light sensing device 400, the photoelectric current is not injected into the second semiconductor layer 340, but because the photoelectric current is generated in the light absorption layer 170, the field applied to the second semiconductor layer 340 may vary. When the field applied to the second semiconductor layer 340 is changed, an amount of carriers flowing through the second semiconductor layer 340 may also be changed. Because the change in the field applied to the second semiconductor layer 340 is due to the photoelectric current generated in the light absorption layer 170, the intensity of light incident on the light absorption layer 170 may be measured by measuring the change in the amount of carriers flowing in the second semiconductor layer 340 according to the change in the field applied to the second semiconductor layer 340.

FIG. 5 shows a fifth light sensing device 500 according to an example embodiment. Description of elements similar to those as described above may be omitted.

Referring to FIG. 5, a substrate 510 of the fifth light sensing device 500 includes only a lower layer 520 and an upper layer 540 sequentially stacked. The lower layer 520 and the upper layer 540 may directly contact each other, or may not directly contact each other in other embodiments. The composition and layer structure of the stack formed on the substrate 510 may be the same as that of the fourth light sensing device 400. The lower layer 520 may be or may include an insulating layer. The upper layer 540 may be a channel layer.

In one example, the lower layer 520 may correspond to the intermediate layer 330 of the fourth light sensing device 400, and thus, the lower layer 520 may be of the same material as the intermediate layer 330 or include such a material. but the lower layer 520 may include an insulating material different from that of the intermediate layer 330.

In one example, the upper layer 540 may correspond to the upper layer 340 of the fourth light sensing device 400, and thus, the upper layer 540 may be of the same material as the upper layer 340 of the fourth light sensing device 400, or may include such a material.

Comparing the fourth light sensing device 400 and the fifth light sensing device 500 with each other, the fifth light sensing device 500 may be seen as a result that the lower layer 320 serving as a lower gate electrode in the fourth light sensing device 400 is removed.

As a result, the fifth light sensing device 500 may be regarded as a light sensing device in which the light absorption layer 170 is coupled to a field effect transistor having only an upper gate electrode.

In the fourth and fifth light sensing devices 400 and 500, a photoelectric current generated in the light absorption layer 170 is not injected into the upper layers (i.e., channel layers) 340 and 540 and affects the fields of the upper layers 340 and 540. Accordingly, the light absorption layer 170 of the fourth and fifth light sensing devices 400 and 500 may be referred to as an indirect light gate rather than a direct light gate that supplies a photoelectric current to a channel.

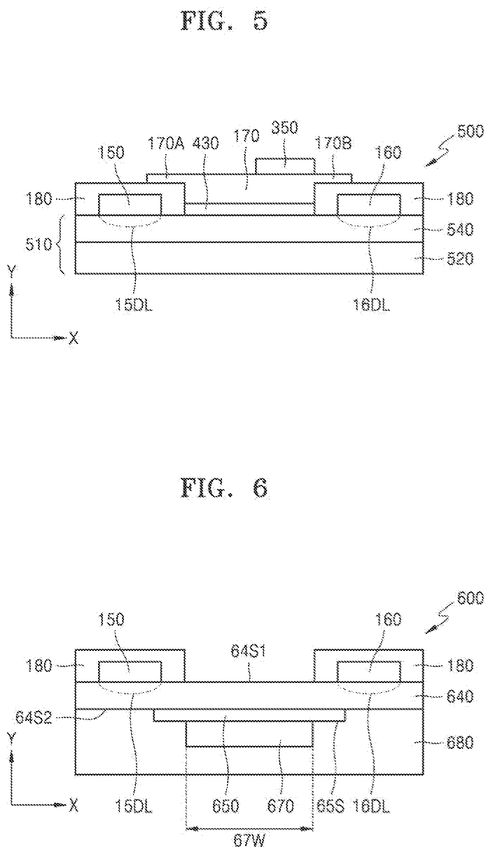

FIG. 6 shows a sixth light sensing device 600 according to an example embodiment. Description of elements similar to those as described above may be omitted.

Referring to FIG. 6, the sixth light sensing device 600 includes a channel layer 640, first and second electrodes 150 and 160 formed on a first surface 64S1 of the channel layer 640, and a light absorption layer 670 formed on a second surface 64S2 of the channel layer 640. The first surface 64S1 may be a surface opposite to the second surface 64S2.

In this description, the first surface 64S1 may be referred to as an upper surface of the channel layer 640, and the second surface 64S2 may be referred to as a lower surface or bottom surface of the channel layer 640, but may change depending on various perspectives. That is, the first surface 64S1 or the second surface 64S2 may be referred to as a side surface or an inclined surface.

On the first surface 64S1, the first electrode 150 and the second electrode 160 are spaced apart from each other. When light is incident on the first surface 64S1, a distance between the first electrode 150 and the second electrode 160 may be a factor that limits the size of a window that limits a region where the light is incident on the light absorption layer 670. The first and second electrodes 150 and 160 may be covered with an insulating layer 180.

The channel layer 640 and the light absorption layer 670 may be provided so as not to directly contact each other. To this end, an interlayer insulating layer 650 transparent to incident light may be provided between the channel layer 640 and the light absorption layer 670. The interlayer insulating layer 650 may be used as a gate insulating layer. The interlayer insulating layer 650 directly contacts the second surface 64S2 of the channel layer 640 and covers the second surface 64S2 between the first electrode 150 and the second electrode 160. On the second surface 64S2, the interlayer insulating layer 650 may extend onto the first and second electrodes 150 and 160. In one example, the interlayer insulating layer 650 may extend to overlap a portion of the first and second electrodes 150 and 160 with the channel layer 640 therebetween, and may extend to overlap the whole of the first and second electrodes 150 and 160.

The light absorption layer 670 may be provided on a lower surface 65S of the interlayer insulating layer 650. The light absorption layer 670 may be provided on a portion of the lower surface 65S or may be provided to cover the entire lower surface 65S. In other words, a width 67W of the light absorption layer 670 in the horizontal direction may be equal to or less than a width of the interlayer insulating layer 650.

An insulating layer 680 covering the interlayer insulating layer 650 and the light absorption layer 670 sequentially stacked may be provided on the second surface 64S2 of the channel layer 640. The insulating layer 680 may be of a material that is transparent to incident light or may be opaque to incident light. For example, when light is incident from below the channel layer 640, the insulating layer 680 may be of a material that is transparent to light, but when light is incident from above the channel layer 640, the insulating layer 680 may be opaque to incident light. The insulating layer 680 may be provided to cover the entire second surface 64S2 of the channel layer 640 around the interlayer insulating layer 650, or may be provided to cover only a portion of the second surface 64S2.

In one example, the insulating layer 680 may be of the same material as the lower layer 520 of the fifth light sensing device 500 or may include such a material.

In one example, the channel layer 640 may be of the same material as the upper layer 540 of the fifth light sensing device 500 or may include such a material, but the channel layer 640 is not limited thereto.

In one example, the interlayer insulating layer 650 may be of the same material as the insulating layer 430 of the fifth light sensing device 500 or may include such a material, but the interlayer insulating layer is not limited thereto.

In one example, the light absorption layer 670 may be of the same material as the light absorption layer 170 of the fifth light sensing device 500 or may include such a material, but the light absorption layer 670 is not limited thereto.

The sixth light sensing device 600 does not include a gate electrode, and the interlayer insulating layer 650 is formed between the light absorption layer 670 and the channel layer 640, and thus, the light absorption layer 670 and the channel layer 640 do not contact each other. Accordingly, in the sixth light sensing device 600, the light absorption layer 670 may act as an indirect light gate affecting a field of the channel layer 640.

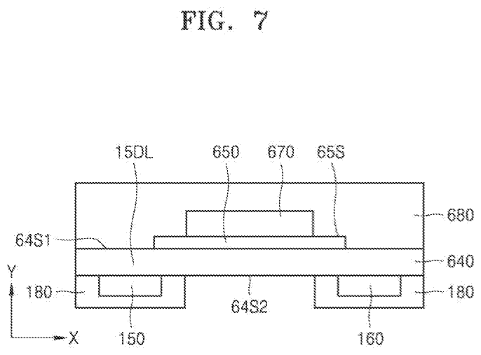

Referring to FIG. 7, in one example, the sixth light sensing device 600 may be upside down. That is, the first and second electrodes 150 and 160 are provided on the second surface 64S2 of the channel layer 640, and the interlayer insulating layer 650, the light absorption layer 670, and the insulating layer 680 may be provided on the first surface 64S1 of the channel layer 640.

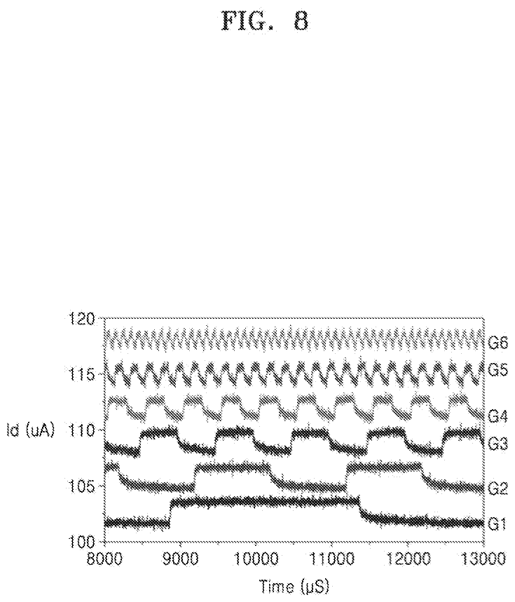

FIG. 8 is a graph showing results of an experiment conducted to confirm a light response of a light sensing device according to an example embodiment. That is, FIG. 8 shows an experimental result of a light gate operation of a light absorption layer included in a light sensing device according to an example embodiment.

In the experiment to obtain the results of FIG. 8, the first light sensing device 100 of FIG. 1 was used as an experimental light sensing device, a p-Si layer was used as the first semiconductor layer 120, an n-Si layer was used as the second semiconductor layer 130, and a depletion layer formed by junction of the first and second semiconductor layers 120 and 130 was used as the interlayer insulating layer 140. An undoped amorphous Ge layer was used as the light absorption layer 170. The Ge layer was formed to a thickness of about 30 nm using an e-beam evaporator. In addition, in the experiment, a laser light source emitting a laser having a wavelength of 1310 nm was used as a light source for illuminating the light sensing device.

The experiment was conducted by repeating laser irradiation (ON) and laser irradiation stop (OFF) with respect to the first light sensing device 100, and measuring a photoelectric current at the ON and OFF states. In this experiment, the ON/OFF repetition rate of the laser (the number of ON/OFF repetitions per second), that is, the switching speed of the laser is varied, and a light response (e.g., photoelectric current) of the first light sensing device 100 is measured at each switching speed. This experiment was conducted while changing the switching speed of the laser from 200 Hz to 10 kHz.

FIG. 8 shows the result of the light response of the first light sensing device 100 when the switching speed of the laser is 200 Hz, 500 Hz, 1 kHz, 2 kHz, 5 kHz, and 10 kHz.

In FIG. 8, the horizontal axis represents time (microseconds), and the vertical axis represents a photoelectric current flowing between a source and a drain (i.e., the photoelectric current flowing in the channel).

In FIG. 8, the first line G1 shows a result when the switching speed of the laser is 200 Hz, the second line G2 shows a result when the switching speed of the laser is 500 Hz, the third line G3 shows a result when the switching speed of the laser is 1 kHz, the fourth line G4 shows a result when the switching speed of the laser is 2 kHz, the fifth line G5 is a result when the switching speed of the laser is 5 kHz, and the sixth line G6 shows a result when the switching speed of the laser is 10 kHz.

Referring to FIG. 8, it may be seen that the photoelectric current corresponding to the ON/OFF of the laser is measured at each switching speed of the laser. These results show that the light absorption layer 170 of the first light sensing device 100 functions as a light gate.

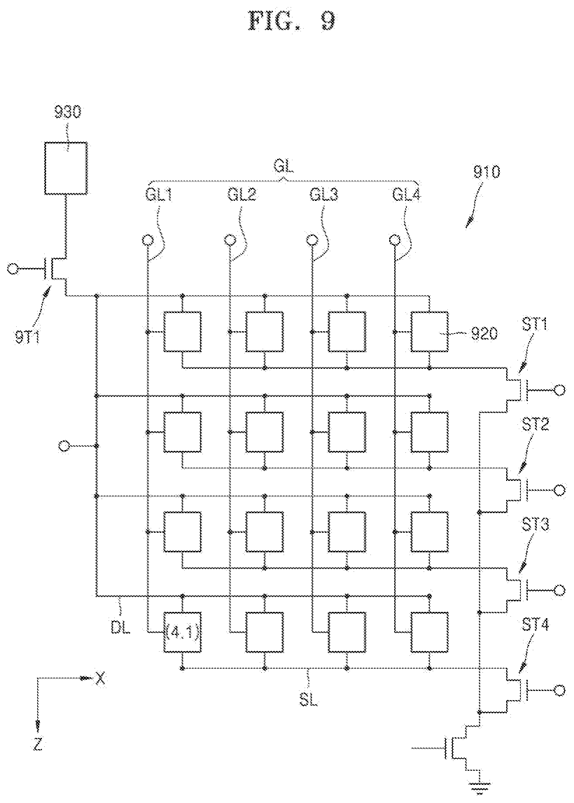

FIG. 9 is a diagram illustrating a pixel array of an infrared image sensor according to an example embodiment. FIG. 9 shows a pixel array 910 of an image sensor according to an example embodiment. In one example, the pixel array 910 may be a pixel array of an infrared image sensor, but the pixel array 910 is not limited thereto.

The pixel array 910 includes a plurality of pixels 920 aligned in two directions perpendicular to each other. The plurality of pixels 920 are arranged at first intervals in the horizontal direction (e.g., the X-axis direction), and are arranged at second intervals in the vertical direction (e.g., a direction parallel to the Z-axis). The first and second intervals may be equal to each other, but may also be different from each other.

In other words, the plurality of pixels 920 are arranged to form a plurality of rows and a plurality of columns. For example, one row may include four pixels 920 arranged at regular intervals, and one column may include four pixels 920 arranged at regular intervals. Each row and column may include four or more pixels or four or less pixels, and the intervals between the pixels 920 constituting a row may be different from the intervals between the pixels 920 constituting a column.

Gate electrodes of the pixels 920 included in one column may be commonly connected to one of the gate lines GL1 to GL4. The pixel array 910 may have a plurality of gate lines GL1 to GL4 corresponding to the number of columns. That is, the plurality of gate lines GL1 to GL4 may be configured to correspond to the plurality of columns on a one-to-one basis. A voltage may be applied to the gate electrode of the pixels 920 through the plurality of gate lines GL1 to GL4.

Drain electrodes of the pixels 920 included in one row may be commonly connected to one drain line DL. The pixel array 910 has a plurality of drain lines DL corresponding to the number of rows, and the plurality of drain lines DL may be configured to correspond to the plurality of rows on a one-to-one basis. The plurality of drain lines DL are connected to a transistor 9T1 that controls a voltage, and the transistor 9T1 is connected to a power source 930. A voltage may be supplied from the power source 930 to the plurality of pixels 920 connected to the drain line DL through the plurality of drain lines DL. The voltage supply may be regulated by the transistor 9T1.

The pixel array 910 includes a plurality of source lines SL, and the plurality of source lines SL may be configured to correspond to a plurality of rows on a one-to-one basis. One source line may be commonly connected to the source electrodes of the pixels 920 forming one row.

A plurality of source select transistors ST1 to ST4 are provided in the pixel array 910. The plurality of source select transistors ST1 to ST4 may correspond to (connect) one-to-one with the plurality of source lines SL. Each source line SL is connected to source electrodes of corresponding source select transistors ST1 to ST4.

In view of the selection of the pixels 920 in the pixel array 910, a voltage is applied from the power source 930 to the drain electrodes of the plurality of pixels 920 while the transistor 9T1 that controls a voltage is turned on. At the same time, one pixel 920 may be selected while the gate line GL and the source select transistors ST1 to ST4 are selected. For example, in a state that a voltage is applied to the drain electrodes of the plurality of pixels 920, when the first gate line GL1 is selected and the fourth source select transistor ST4 is selected, the pixel (4, 1) in row 4 and column 1 of the pixel array 910 may be selected.

The selection of the fourth source select transistor ST4 may denote that only the fourth source select transistor ST4 among the source select transistors ST1 to ST4 is turned on and the others are turned off.

In one example, the pixel 920 may be one of the light sensing devices illustrated in FIGS. 1 to 7, a combination thereof, or one of light sensing devices inferred therefrom.

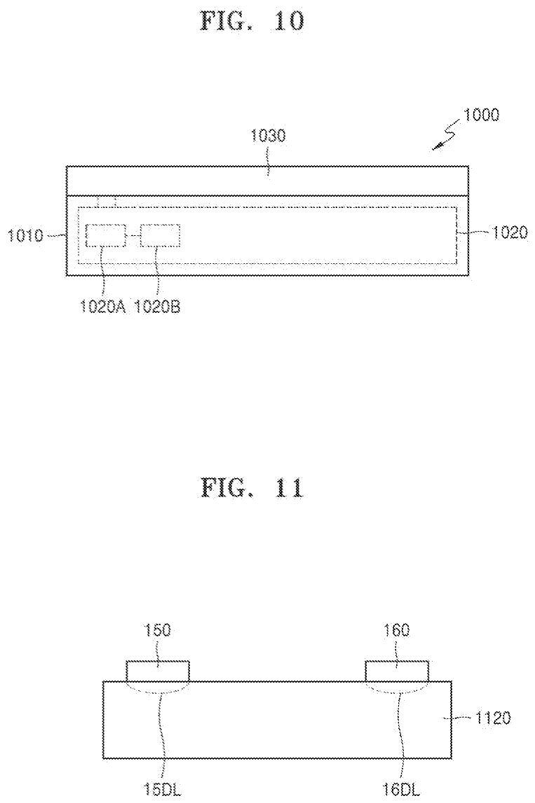

FIG. 10 is a cross-sectional view illustrating an image sensor including the pixel array of FIG. 9 according to an example embodiment. FIG. 10 shows an image sensor 1000 according to an example embodiment. The image sensor 1000 may be an infrared image sensor.

Referring to FIG. 10, the image sensor 1000 may include a substrate 1010 including a circuit unit 1020 and a pixel layer 1030 provided on the substrate 1010, but may not be limited thereto. In one example, the pixel layer 1030 may include the pixel array 910 illustrated in FIG. 9. In one example, the circuit unit 1020 may be or include a circuit (e.g., a readout IC (ROIC)) for processing a signal (e.g., an electrical signal including a photoelectric current) generated in the pixel layer 1030. Reference numeral 1020A denotes a reference pixel included in the circuit, and 1020B denotes a capacitive transimpedance amplifier connected to the reference pixel 1020A. The reference pixel 1020A generates a reference current for comparison with a current given from a corresponding pixel of the pixel layer 1030. To this end, a voltage may be applied to the reference pixel 1020A.

The circuit unit 1020 may include a plurality of reference pixels 1020A that may correspond to pixels of the pixel layer 1030 on a one-to-one basis.

In the operation of the image sensor 1000, a current generated from one selected pixel of the pixel layer 1030 (hereinafter referred to as a first current) may include a photoelectric current generated by incident light together with a basic current (dark current). When the first current is transmitted to the circuit unit 1020, the first current is compared with a reference current generated from the reference pixel 1020A in the circuit unit 1020, and a current corresponding to the reference current is removed from the first current. As a result, because only a current corresponding to the photoelectric current generated in the selected pixel remains in the first current, the photoelectric current generated in the selected pixel may be measured.

Through the comparison, a remaining current after a current corresponding to the reference current is removed from the first current may be amplified by the capacitive transimpedance amplifier 1020B. An image processing processor for processing an electrical signal (e.g., an image signal) output from the amplifier 1020B may be connected to the capacitive transimpedance amplifier 1020B.

Next, methods of manufacturing light sensing devices according to example embodiments will be described in detail with reference to FIGS. 11 to 24. In the following description, the same reference numerals as those mentioned in the previous structural description denote the same members, and descriptions thereof may be omitted.

FIGS. 11, 12, 13, 14, 15 and 16 are cross-sectional views illustrating a method of manufacturing a light sensing device, according to an example embodiment.

Referring to FIG. 11, first and second electrodes 150 and 160 are formed on a substrate 1120. In one example, the substrate 1120 may be formed to have a layer structure in which an upper layer may be used as a channel.

For example, the substrate 1120 may be formed by sequentially stacking the first semiconductor layer 120, the interlayer insulating layer 140, and the second semiconductor layer 130 of FIG. 1. For example, the substrate 1120 may be formed to have a layer structure corresponding to the substrate 310 of FIG. 3. For example, the substrate 1120 may be formed to have a layer structure corresponding to the substrate 510 of FIG. 5.

The first and second electrodes 150 and 160 may be formed to be spaced apart from each other by a set interval in consideration of the formation of the light absorption layer. The first and second electrodes 150 and 160 may be formed in a method in which, after forming on the substrate 1120 a conductive layer that may be used as an electrode, the conductive layer is removed except for portions corresponding to the first and second electrodes 150 and 160 using a photolithography process that is implemented in a process of manufacturing a semiconductor device. Alternatively, a mask pattern exposing (limiting) a region where the first and second electrodes 150 and 160 are to be formed is first formed on the substrate 1120, and after forming the conductive layer on the exposed substrate 1120, the first and second electrodes 150 and 160 may be formed by removing the mask pattern.

In one example, before the first and second electrodes 150 and 160 are formed, doped regions 15DL and 16DL may be formed by doping partial regions of the substrate 1120 corresponding to the first and second electrodes 150 and 160.

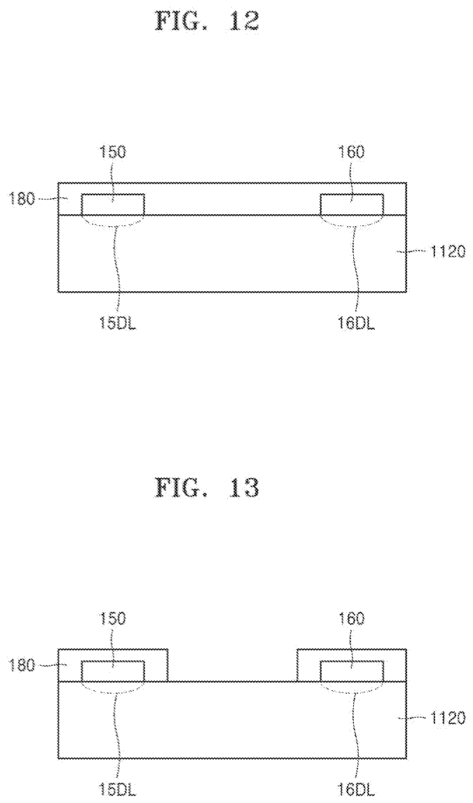

After forming the first and second electrodes 150 and 160, as shown in FIG. 12, an insulating layer 180 covering the first and second electrodes 150 and 160 is formed on the substrate 1120. A planarization process may be performed on an upper surface of the insulating layer 180.

After forming the insulating layer 180, as shown in FIG. 13, an upper surface of the substrate 1120 is exposed by removing a portion of the insulating layer 180 between the first and second electrodes 150 and 160

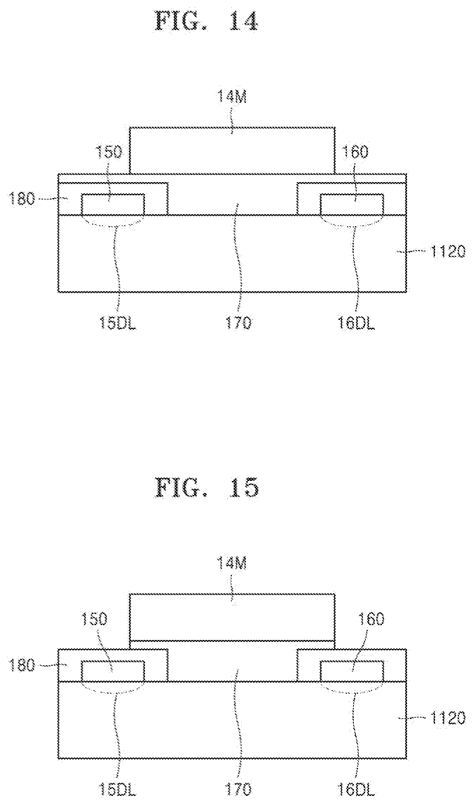

Next, as shown in FIG. 14, a light absorption layer 170 is formed on the exposed upper surface of the substrate 1120. The light absorption layer 170 may be formed by using various stacking methods, for example, a chemical vapor deposition (CVD) method, a physical vapor deposition (PVD) method, or a sputtering method, but the formation of the light absorption layer 170 is not limited thereto. The light absorption layer 170 may be formed by using a growing method.

The light absorption layer 170 may be formed to cover the entire substrate 1120 between the first and second electrodes 150 and 160. The light absorption layer 170 may be formed to fill between the first and second electrodes 150 and 160 (i.e., to fill/cover an area corresponding to the portion of the insulating layer 180 that was removed as shown in FIG. 13) and extend onto the insulating layer 180. The light absorption layer 170 may be formed to cover an entire upper surface of the insulating layer 180. An upper surface of the light absorption layer 170 formed in this way may be flattened through a planarization process. A mask pattern 14M is formed on the light absorption layer 170. The mask pattern 14M may be formed to cover the light absorption layer 170 between the first and second electrodes 150 and 160. The mask pattern 14M may also be formed to cover a portion of the light absorption layer 170 formed on the insulating layer 180, and may also be formed to cover portions of the first and second electrodes 150 and 160. The mask pattern 14M may be a photoresist pattern.

After forming the mask pattern 14M, as shown in FIG. 15, the light absorption layer 170 around the mask pattern 14M is removed. The removal of the light absorption layer 170 around the mask pattern 14M may be performed by using a dry etching method, but the method of removal of the light absorption layer 170 is not limited thereto.

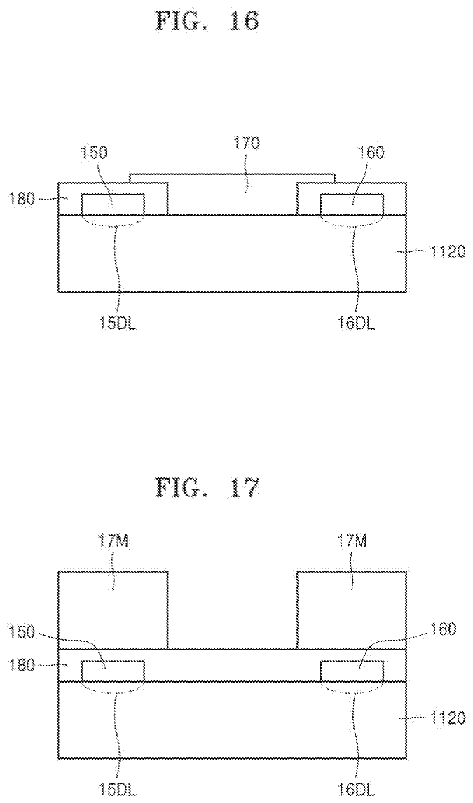

Referring to FIG. 16, after removing the light absorption layer 170 around the mask pattern 14M, the mask pattern 14M is removed. FIG. 16 shows a result of removing the mask pattern 14M.

FIGS. 17, 18, 19 and 20 are cross-sectional views illustrating a method of manufacturing a light sensing device, according to an example embodiment. In one example, after forming the insulating layer 180 in FIG. 12, processes illustrated in FIGS. 17 to 20 may be performed.

Specifically, after forming the insulating layer 180, as shown in FIG. 17, a mask pattern 17M may be formed on the insulating layer 180 to limit a region where a light absorption layer is to be formed. The mask pattern 17M may be formed to completely cover the first and second electrodes 150 and 160 and to expose the insulating layer 180 between the first and second electrodes 150 and 160. The mask pattern 17M may be a photoresist film pattern.

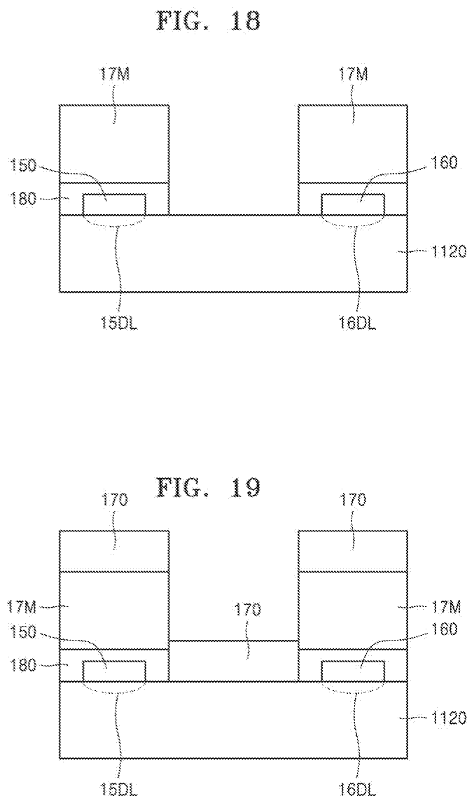

Next, as shown in FIG. 18, the exposed portion of the insulating layer 180 is removed to expose the substrate 1120.

Next, as shown in FIG. 19, a light absorption layer 170 is formed on the exposed substrate 1120 between the first and second electrodes 150 and 160. The light absorption layer 170 may be formed to cover the entire exposed surface of the substrate 1120. The light absorption layer 170 may be formed to have the same thickness as the insulating layer 180 or to be greater or less than the insulating layer 180. The light absorption layer 170 may also be formed on the mask pattern 17M.

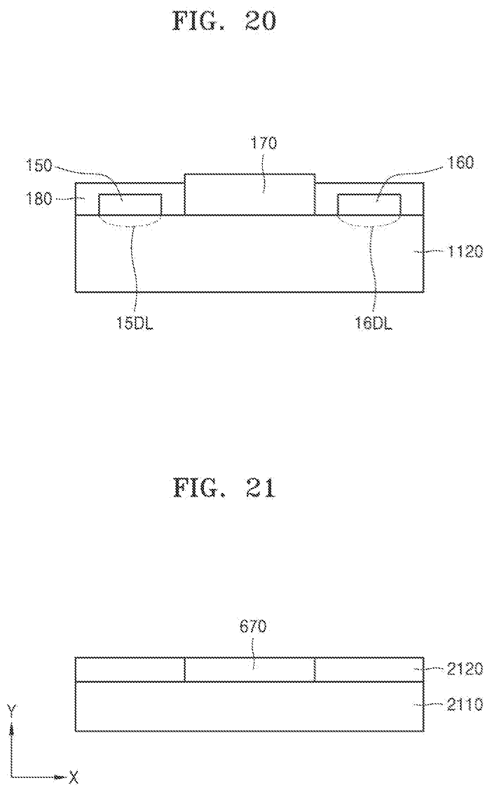

As shown in FIG. 20, after the light absorption layer 170 is formed, the mask pattern 17M is removed. As the mask pattern 17M is removed, the light absorption layer 170 formed on the mask pattern 17M is also removed.

In one example, an insulating layer corresponding to a gate insulating layer may be formed between the light absorption layer 170 and the substrate 1120 in FIG. 14 or 19.

In one example, in the resultant products of FIGS. 16 and 20, an electrode material layer corresponding to the third electrode 350 may further be formed on the light absorption layer 170.

In one example, in the resultant products of FIGS. 14 and 19, the light absorption layer 170 may be formed to a multilayer structure including a plurality of light absorption layers sequentially stacked.

FIGS. 21, 22, 23 and 24 are cross-sectional views illustrating a method of manufacturing a light sensing device, according to an example embodiment.

First, as shown in FIG. 21, a light absorption layer 670 is formed on a partial region of a first insulating layer 2110. The light absorption layer 670 may be formed by using a CVD method, a PVD method, a sputtering method, or a growing method, but the formation of the light absorption layer 670 is not limited thereto. In one example, the first insulating layer 2110 may include the same material as the intermediate layer 330 of FIG. 3, but may also include different insulating materials from each other.

A second insulating layer 2120 is formed on the first insulating layer 2110 around the light absorption layer 670. The second insulating layer 2120 may be formed to cover an entire upper surface of the first insulating layer 2110 around the light absorption layer 670. In one example, the second insulating layer 2120 may include the same material as the first insulating layer 2110, but may include different materials from each other. The second insulating layer 2120 may be formed at the same or substantially the same height as the light absorption layer 670. Accordingly, an upper surface of the second insulating layer 2120 and an upper surface of the light absorption layer 670 may be planes having the same height.

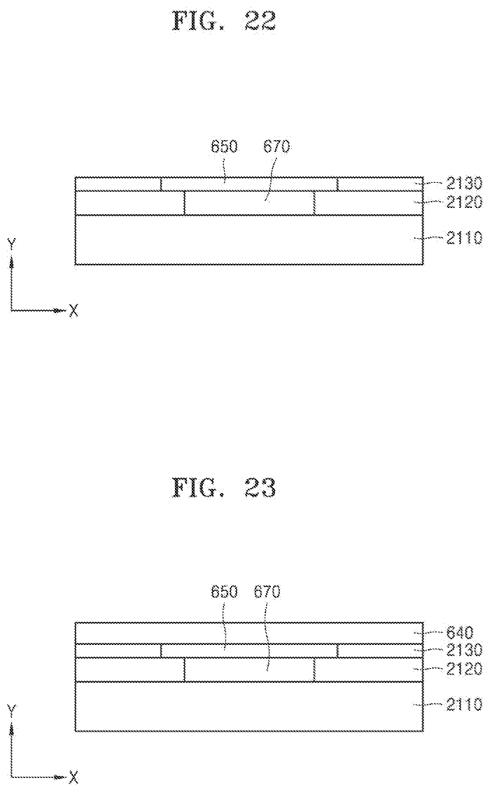

Next, as shown in FIG. 22, an interlayer insulating layer 650 is formed on the light absorption layer 670. The interlayer insulating layer 650 may be formed to cover an entire upper surface of the light absorption layer 670 and also to cover a portion of the upper surface of the second insulating layer 2120 around the light absorption layer 670. A third insulating layer 2130 is formed on the second insulating layer 2120 around the interlayer insulating layer 650. In one example, the third insulating layer 2130 may include the same material as the first insulating layer 2110, but may include different materials from each other. The third insulating layer 2130 may be formed at the same height as the interlayer insulating layer 650, but may be formed at a different height from the interlayer insulating layer 650.

Next, as shown in FIG. 23, a channel layer 640 covering the interlayer insulating layer 650 and the third insulating layer 2130 is formed. The channel layer 640 may be formed to cover an entire upper surface of the interlayer insulating layer 650 and an entire upper surface of the third insulating layer 2130, but may be formed differently. For example, the channel layer 640 may be formed to cover the entire upper surface of the interlayer insulating layer 650 that performs as a gate insulating layer and only a portion of the upper surface of the third insulating layer 2130.

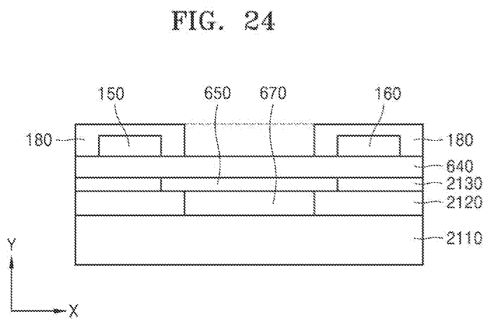

Next, as shown in FIG. 24, first and second electrodes 150 and 160 spaced apart from each other are formed on the upper surface of the channel layer 640, and then an insulating layer 180 surrounding the first and second electrodes 150 and 160 is formed. When the insulating layer 180 is transparent to infrared rays or has a low infrared absorption rate, the insulating layer 180 may be formed to cover even the channel layer 640 between the first and second electrodes 150 and 160.

In one example, as shown in FIG. 24, when the insulating layer 180 is not formed on a region of the channel layer 640 corresponding to the light absorption layer 670, a second light absorption layer may be formed on the corresponding region of the channel layer 640 as indicated by a dotted line. In one example, the second light absorption layer may be formed according to the process illustrated above. In one example, the second light absorption layer and the light absorption layer 670 formed under the channel layer 640 may include the same material or different materials from each other. In one example, the second light absorption layer may include a material absorbing infrared rays of a first wavelength, and the light absorption layer 670 may include a material absorbing infrared rays of a second wavelength different from the first wavelength. In one example, the light absorption layer 670 may include a doped Si layer, and the second light absorption layer may include a doped Ge layer or vice versa.

The light sensing device and/or the image sensor including the light sensing devices according to the example embodiments described above may be used in various electronic devices (e.g., LiDAR, mobile phone, recognition device, various identification devices, radar, etc.) utilizing infrared rays.

The disclosed light sensing devices are implemented by applying a light absorption layer to a silicon-based field effect transistor. Therefore, the light sensing devices may be easily manufactured using a process of manufacturing a silicon semiconductor device. In addition, the light absorption layer may use a semiconductor material (e.g., Ge or Si) doped as a material for absorbing infrared rays. Therefore, the light absorption layer may be formed by a deposition method and may be formed in a large area. Accordingly, the manufacturing cost of the light sensing device may be reduced, and the manufacturing cost of an image sensor including a pixel array including a plurality of light sensing devices may also be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light sensing device comprising:
a channel layer;
a first electrode provided on a first surface of the channel layer;
a second electrode provided on the first surface of the channel layer and spaced apart from the first electrode; and
a light absorption layer provided on the channel layer between the first electrode and the second electrode and configured to absorb infrared rays,
wherein the light absorption layer comprises a doped semiconductor layer.

2. The light sensing device of claim 1, wherein the channel layer comprises an n-type semiconductor layer.

3. The light sensing device of claim 1, wherein the light absorption layer directly contacts the first surface of the channel layer.

4. The light sensing device of claim 1, wherein the channel layer comprises:
a first doped region corresponding to the first electrode; and
a second doped region corresponding to the second electrode.

5. The light sensing device of claim 1, wherein the light absorption layer comprises a doped Ge layer or a doped Si layer.

6. The light sensing device of claim 1, wherein the doped semiconductor layer is amorphous or polycrystalline.

7. A light sensing device comprising:
an insulating layer;
a channel layer provided on the insulating layer;
a first electrode provided on a first surface of the channel layer;
a second electrode provided on the first surface of the channel layer and spaced apart from the first electrode;
a light absorption layer provided on the channel layer between the first electrode and the second electrode and configured to absorb infrared rays; and
a gate insulating layer provided between the channel layer and the light absorption layer,
wherein the channel layer comprises an n-type semiconductor layer, and
wherein the light absorption layer comprises an undoped semiconductor layer.

8. The light sensing device of claim 7, wherein the light absorption layer is provided between the insulating layer and the channel layer, and
wherein the light absorption layer and the gate insulating layer are at least partially covered by the insulating layer.

9. The light sensing device of claim 8, further comprising a first semiconductor layer,
wherein the insulating layer is between the first semiconductor layer and the channel layer.

10. The light sensing device of claim 9, wherein the first semiconductor layer comprises a p-type semiconductor layer.

11. The light sensing device of claim 9, wherein the first semiconductor layer comprises a semiconductor layer of a type that is the same as a type of the channel layer.

12. The light sensing device of claim 7, wherein the channel layer comprises a first doped region corresponding to the first electrode and a second doped region corresponding to the second electrode.

13. The light sensing device of claim 7, wherein the light absorption layer comprises a Ge layer.

14. A method of manufacturing a light sensing device, the method comprising:
forming a first electrode and a second electrode on a first surface of a substrate, the first electrode and the second electrode being spaced apart from each other; and
forming a light absorption layer on the substrate between the first electrode and the second electrode, the light absorption layer being configured to absorb infrared rays,
wherein the light absorption layer comprises a doped Ge layer or a doped Si layer.

15. The method of claim 14, wherein the substrate comprises a gate electrode.

16. The method of claim 15, wherein the substrate comprises a PN junction semiconductor layer,
wherein the PN junction semiconductor layer comprises a P-type semiconductor layer; and
wherein the gate electrode comprises the P-type semiconductor layer of the PN junction semiconductor layer.

17. The method of claim 14, further comprising:
forming an insulating layer on the substrate, the insulating layer covering the first electrode and the second electrode; and
removing a portion of the insulating layer that is between the first electrode and the second electrode.

18. The method of claim 17, wherein the light absorption layer is formed to fill an area between the first electrode and the second electrode corresponding to the portion of the insulating layer that is removed, and
wherein the light absorption layer extends onto the insulating layer.

19. The method of claim 14, further comprising:
forming an insulating layer on the substrate, the insulating layer covering the first electrode and the second electrode;
forming a mask pattern comprising a first portion covering the first electrode and a second portion covering the second electrode; and
removing a portion of the insulating layer between the first portion of the mask pattern and the second portion of the mask pattern.

20. The method of claim 19, wherein the light absorption layer is formed in an area corresponding to the removed portion of the insulating layer.
